(19) United States
(12) Patent Application Publication
(10) Pub. No.: US 2022/0339899 A1
(43) Pub. Date: Oct. 27, 2022

(54) Automatic Roll-to-Roll Quick Press for Flexible Plates

(71) Applicant: Xiamen University of Technology, Xiamen (CN)

(72) Inventors: An Xie, Xiamen (CN); Dongya Sun, Xiamen (CN); Chunyan Cao, Xiamen (CN); Yuechan Li, Xiamen (CN); Xiangjun Lu, Xiamen (CN); Liang Yang, Xiamen (CN)

(21) Appl. No.: 17/542,546

(22) Filed: Dec. 6, 2021

(30) Foreign Application Priority Data
Apr. 25, 2021 (CN) 202110445859.3

(51) Int. Cl. B30B 15/00; B30B 1/00; B30B 15/06

(52) U.S. Cl. CPC B30B 15/0052; B30B 1/007; B30B 15/064; B30B 15/041

(57) ABSTRACT

Provided is an automatic roll-to-roll quick press for flexible plates. The quick press comprises a lower film part and an upper film part parallel and movably attached to the lower film part. A right end of the lower film part is vertically connected to a transmission belt; a right end of the transmission belt is connected with a first pressing part; a top of the first pressing part is connected with a second pressing part; a second pressing plate part of the second pressing part comprises a flatness detection tube; there are four large infrared detectors inside the flatness detection tube, and four small infrared detectors inside; the detector scans a total of eight directions, and the scanning area covers the entire cylinder.

### CROSS REFERENCE OF RELATED APPLICATIONS

The present disclosure claims the benefit of Chinese Patent Application No. 202110445859.3 entitled “Automatic Roll-to-Roll Quick Press for Flexible Plate,” filed on Apr. 25, 2021, in the China National Intellectual Property Administration, the entire content of which is incorporated herein in its entirety.

### TECHNICAL FIELD

The present disclosure relates to the technical field of roll-to-roll manufacturing for flexible plate, in particularly to an automatic roll-to-roll quick press for flexible plates.

### BACKGROUND

When the flexible circuit board is manufactured, after exposure, development and etching, the flexible circuit board needs to be pressed together, and the reinforcing film or the reinforcing board and the circuit board are pressed together. The pressing is matched by high temperature and high pressure, so it is also necessary Lay a layer of high temperature film on the circuit board to prevent damage to the circuit board. When pressing, a fast press is usually used.

Based on the above description, the inventor found that the existing flexible roll-to-roll automatic fast press mainly has the following shortcomings, such as:

1. When pressing, the upper and lower steel plates cooperate with each other. However, when the steel plate is working under high temperature and high pressure for a long time or encounters interference from other materials, it is easy to deform. The deformed steel plate is difficult to observe with the naked eye. When pressing the circuit board, it is easy to cause air bubbles on the surface of the pressed circuit board, which can easily block the normal passage between the two circuits, and is not sensitive when used.

2. When the adhesive is fast pressed, the instantaneous strong pressure can easily cause glue overflow. The overflowed glue is not only wasted, but also easily solidifies on the circuit board and affects other components. It may also affect the original need for adhesion. The colloid extrusion affects the adhesion of the reinforcing plate, and it may fall off during the later transfer and use.

### SUMMARY

The purpose of the present disclosure is to provide a circulating aquaculture facility for saltwater ponds, aiming to improve the existing circulating aquaculture facilities that fails separate fish and shrimp in different environments, and clean up fish and shrimp excrement properly.

The present disclosure is achieved by an automatic roll-to-roll quick press for flexible plates. The quick press comprises a lower film part and an upper film part parallel and movably attached to the lower film part. A right end of the lower film part is vertically connected to a transmission belt; a right end of the transmission belt is connected with a first pressing part; a top of the first pressing part is connected with a second pressing part; a second pressing plate part of the second pressing part comprises a flatness detection tube; there are four large infrared detectors inside the flatness detection tube, and four small infrared detectors inside; the detector scans a total of eight directions, and the scanning area covers the entire cylinder; inside a center of the second pressing part is hidden a punching bag assembly; the second pressing plate is a seamless smooth surface when the punching bag assembly is not running; a first pressing plate part of the first pressing part comprises four multi-functional processing structures; the four multi-functional processing structures enclose the circuit board tightly; the multi-functional processing structure comprises an internal rotating drum, which is divided into upper and lower parts; an overflow groove on the upper part of the internal rotating drum first contacts the circuit board; and a component that capable of being rotated upwards from the bottom is a heat-sealing clamp.

In some embodiments, the flatness detection cylinder further comprises an L-shaped buckle connected to its left and right ends, one end of a short shaft of the L-shaped buckle is inserted into a shaft center of the flatness detection tube, and one end of the long shaft is fixed with a steering shaft; the steering shaft is vertically inserted and embedded in the sliding wheel; the sliding wheel drives the entire flatness detection cylinder to perform a uniform linear motion in the grooves on the front and back sides of the second pressure plate.

In some embodiments, the punching bag assembly is movably connected to the bottom inside the second pressure plate, and there are four punching bag assemblies; the four punching bag assemblies are distributed on right up, right down, left, and right positions on basis of a top view of the second pressing plate; the top of one end of the punching bag assembly near the outer end is provided with a filling column, which interacts with the second pressing plate when the filling column is not moving; the bottom of the filling column and the bottom of the punching bag assembly are both connected with the hot pressing plate which has a solid structure and better heat conduction effect.

In some embodiments, the end of the multi-functional processing structure close to the outer side of the first press plate is connected with a hydraulic column; the multi-functional processing structure is hidden 3 cm inside the first pressure plate when it is not in operation, and the hydraulic column can be pushed out as soon as it runs; two of the four multi-functional processing structures; both ends are vertically connected with a meshing tooth column, and the meshing tooth columns mesh with each other so that the four multi-functional processing structures form a four-way linkage mechanism; the multi-functional processing structure; the end in contact with the circuit board is an overflow groove, and the dividing line between the overflow groove and the heat sealing clip is the base axis, and each rotation angle is 180°.

In some embodiments, the overflow groove is a semicircular structure with an upward opening, and its bottom is also connected with two reverse flow belts, and two reverse suction openings are connected to the lower left corner and the lower right corner of the overflow groove.

In some embodiments, the two reverse flow belts form a top-sealed figure eight-shaped structure, and the bottom connecting end is chamfered, and a check valve is installed at the top of the joint with the overflow groove.

In some embodiments, the heat-sealing clamp is an inverted bowl-shaped structure, and the left and right ends of the inside are connected with the snap clip; an oval clip with a downward opening is connected in the middle of the snap clip.

In some embodiments, the front and rear ends of the top of the lower station of the lower laminating part are installed with guide rails, the inner part of the guide rail is connected with two chucking wheels, the first chucking wheel in contact with the circuit board is in a static state, and the second chucking wheel is in intermittent motion. In the state, the top corner of the guide rail facing the initial movement direction of the circuit board is connected with a guide piece, and the guide piece is adjusted to an angle of 60°-120° based on the vertical line.

The present disclosure is a flexible plate-to-roll automatic quick press, which has reasonable design and strong functionality, and has the following advantages.

1. Every time when the fast pressing is about to start, the flatness detection tube is first transferred to the second pressing plate through the steering shaft, and then it is translated on the surface of the second pressing plate, and the inner infrared detector detects the plane and the cylinder. The force effect can obtain the flatness of the surface of the second pressure plate, and quickly repair it when it appears concave or convex, which can prevent the defective pressure plate from directly acting on the circuit board without inspection and treatment. No air bubbles are generated on the surface of the lower circuit board, so that the passage between the circuit boards becomes more stable and smoother.

2. The momentary strong pressure will cause the adhesive in the reinforcement board to spread quickly or even overflow, and the overflow glue grooves close to the circuit board will suck in the overflow glue, and store and recover the excess glue through the backflow belt. It will not stay on the surface and affect other components, and it can be replaced by a heat-sealing clip by rotating, which has a plastic effect on the edge of the circuit board, so that the glue at the edge is sealed in advance and transferred to the oven. It is not easy to demold and shift during the process, which improves the accuracy of shaping during thermal baking.

### BRIEF DESCRIPTION OF THE DRAWINGS

In order to explain the technical solutions of the embodiments of the present disclosure more clearly, the following will briefly introduce the drawings that need to be used in the embodiments. It should be understood that the following drawings only show certain embodiments of the present disclosure, and therefore do not It should be regarded as a limitation of the scope. For those of ordinary skill in the art, without creative work, other related drawings can be obtained based on these drawings.

FIG. 1 is a schematic diagram of an automatic roll-to-roll quick press for flexible plates according to embodiments of the present disclosure.

FIG. 2 is a schematic diagram of the second pressing part according to embodiments of the present disclosure.

FIG. 3 is a schematic diagram of the flatness detection tube from top view according to embodiments of the present disclosure.

FIG. 4 is a schematic diagram of the second pressing plate when it is activated according to embodiments of the present disclosure.

FIG. 5 is a schematic diagram of the first pressing plate from top view according to embodiments of the present disclosure.

FIG. 6 is a schematic diagram of multi-functional processing structure from left side view according to embodiments of the present disclosure.

FIG. 7 is a schematic diagram of the up-left component of the lower film part according to embodiments of the present disclosure.

FIG. 8 is a diagram showing the flatness when the surface of the second pressing plate is flat according to embodiments of the present disclosure.

FIG. 9 is a diagram showing the flatness when the surface of the second pressing plate is convex according to embodiments of the present disclosure.

FIG. 10 is a diagram showing the flatness when the surface of the second pressing plate is concave according to embodiments of the present disclosure.

In the drawings: lower film part—80, upper film part—81, second pressing part—82, conveyor belt—83, first pressing part—84, overflow groove—410, rotating drum—411, backflow belt—412, heat—sealing clamp—413, filling column—500, hot pressing plate—511, punching bag assembly—522, sliding wheel—820, steering shaft—821, L-shaped buckle—822, flatness detection tube—823, hydraulic column—840, multi-functional processing structure—841, meshing tooth column—842, guide rail—600, chucking wheel—700, guide piece—800.

### DETAILED DESCRIPTION OF THE EMBODIMENTS

In order to make the objectives, technical solutions, and advantages of the embodiments of the present disclosure clearer, the technical solutions in the embodiments of the present disclosure will be described clearly and completely in conjunction with the accompanying drawings in the embodiments of the present disclosure. Obviously, the described embodiments It is a part of the embodiments of the present disclosure, but not all of the embodiments. Therefore, the following detailed description of the embodiments of the present disclosure provided in the accompanying drawings is not intended to limit the scope of the claimed disclosure, but merely represents selected embodiments of the present disclosure. Based on the embodiments of the present disclosure, all other embodiments obtained by those of ordinary skill in the art without creative work shall fall within the protection scope of the present disclosure.

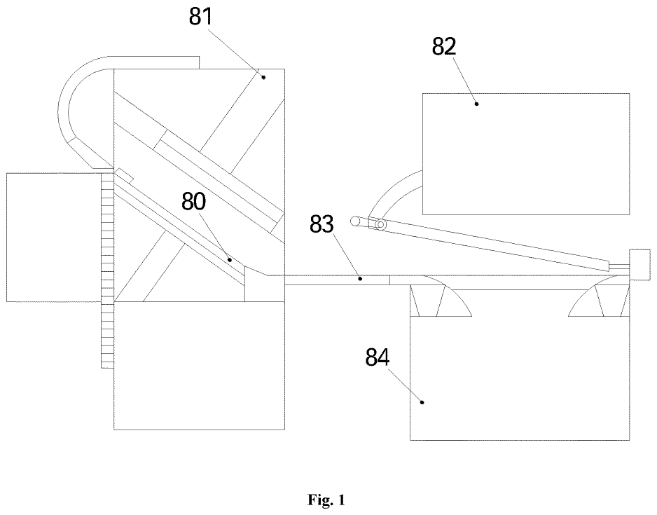

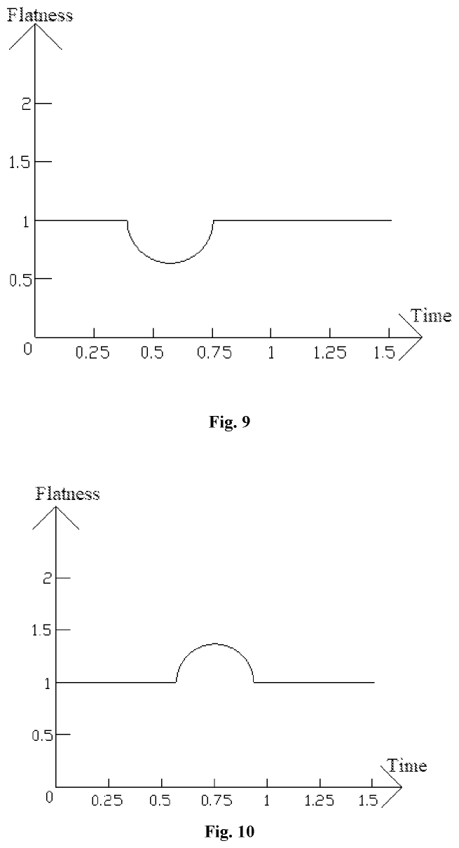

As shown in FIG. 1 to FIG. 10, the present disclosure provides an automatic roll-to-roll quick press for flexible plates. The automatic quick press comprises a lower film part 80 and an upper film part 81 that is parallel and movably attached to the lower film part 80. A transmission belt 83 is also connected vertically to the right end of the lower covering portion 80. The right end of the conveyor belt 83 is connected with a first punching portion 84. The top of the first stamping part 84 is connected with a second stamping part 82. The second pressing plate part of the second stamping portion 82 includes a flatness detecting tube 823. There are four large infrared detectors inside the flatness detecting cylinder 823. Four small infrared detectors are also arranged inside the flatness detection cylinder to scan eight directions in total. The scanning area of the small infrared detector covers the entire cylinder. A punching bag assembly 522 is hidden inside the center of the second stamping portion 82. When the punching bag assembly 522 is not in operation, the entire second pressing plate is a seamless smooth surface. The first pressing plate portion of the first punching portion 84 includes four multi-functional processing structures 841. The four multi-functional processing structures 841 tightly surround the circuit board. The multi-functional processing structure 841 includes a rotating drum 411 inside. The interior of the rotating cylinder is divided into two parts: upper and lower parts. The first contact with the circuit board is the overflow groove 410 in the upper half of the rotating drum 411. The component capable of rotating up at the bottom of the rotating cylinder at any time is a heat sealing clip 413. When the entire cylinder covered by the infrared net rolls on the second pressure plate, every part of the second pressure plate can be detected. When there is a bulge, the trend of infrared rays increases. When there is a depression, the trend of infrared rays decreases. When the state of the second pressing plate is flat, the overall trend is a straight line. The flatness of the steel plate can be known according to the infrared feedback line, and adjustments can be made in time. There is a swinging manipulator at the left end of the upper covering part 81, which can move the circuit board to the position of the lower covering part 80 in one cycle. One cycle time is two and a half minutes, so that the entire feeding process is automated. The left end of the lower film part 80 is provided with a feeding station, and the feeding station will automatically rise by one frame after each circuit board is transferred, so that the circuit board can be continuously fed automatically. The position of one grid is 0.3 cm. The height of the lower film part 80 is 0.3 cm lower than the height of the conveyor belt 83 and can be raised by 0.4 cm after the high temperature film is coated, so that the circuit board after the high temperature film will be pushed out and slide down under the action of gravity. The conveyor belt 83 is conveyed to the lamination area. The lower film part 80 and the upper film part 81 are in a parallel state, and there is no gap in the middle when the two sides are in close contact, so that the high temperature films on both sides can tightly wrap the circuit board.

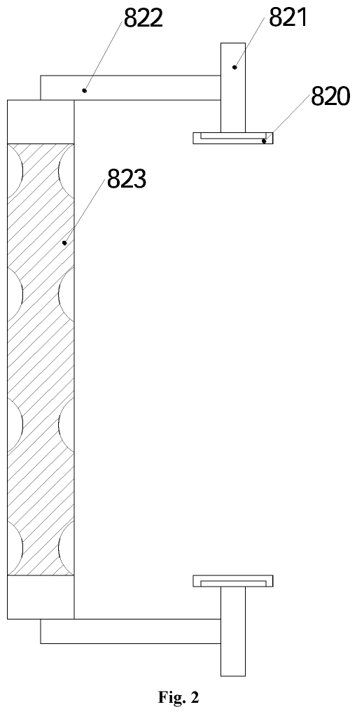

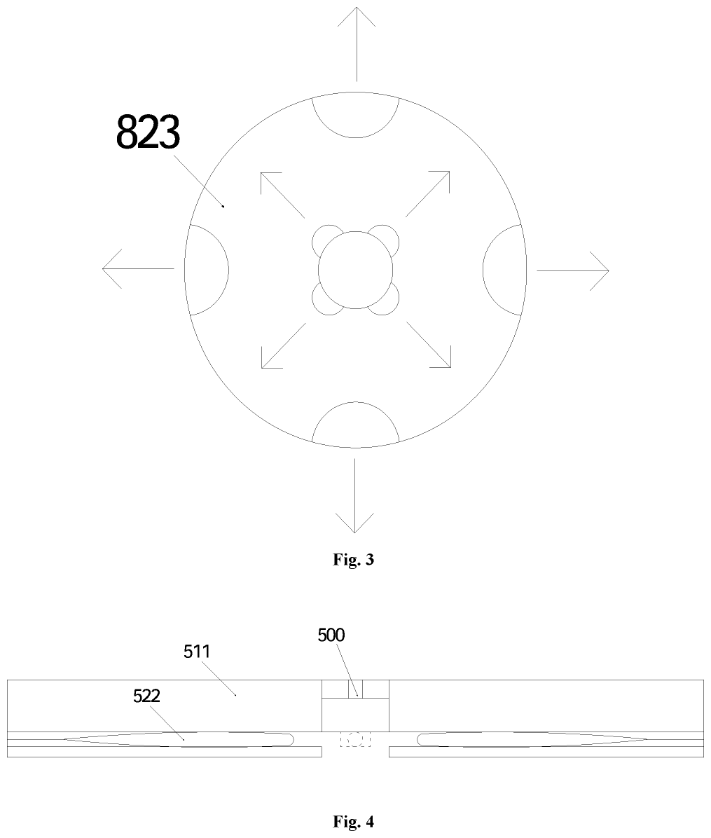

As shown in FIG. 2, FIG. 3, and FIGS. 8-10, the flatness detection tube 823 also comprises L-shaped buckles 822 connected to the left and right ends of the flatness detection tube 823. One end of the short shaft of the L-shaped buckle 822 is inserted into the shaft center of the flatness detection cylinder 823, and one end of the long shaft is fixed to the steering shaft 821 together. The steering shaft 821 is vertically inserted and embedded on the sliding wheel 820. The sliding wheel 820 drives the entire flatness detection cylinder 823 to perform a uniform linear motion in the grooves on the front and rear sides of the second pressure plate. When not in use, the flatness detection cylinder 823 can be rotated through the steering shaft 821 so that it is at the same horizontal line as the second pressing plate and does not interfere with its normal pressing action. The uniform motion of the sliding wheel 820 on both sides of the second pressure plate can span the entire plane of the second pressure plate, cover the entire second pressure plate, and monitor the flatness more accurately without dead spots.

As shown in FIG. 4, the four punching bag assemblies 522 are movably connected in the bottom inside the second pressure plate. The four punching bag components are distributed in four directions up, down, left, and right based on the top view of the second pressing plate. A filling column 500 is provided on the top of the punching bag assembly 522 close to the outer side end. When the filling column is not moving, it completely fits with the bottom of the second pressing plate, which is a seamless connection, and it moves to the upper layer of the bladder assembly 522 when it moves and is not on the same horizontal plane as it. A hot pressing plate 511 is connected to the outer surface of the filling column 500 and the bottom of the punching bag assembly 522. The hot pressing plate has a solid structure and has better heat conduction effect. The speeds at which the bladders 522 are pushed out are equal, which will cause them to squeeze each other from the position where they flow out from under the packing column 500. Take the center position as the base point and squeeze from the surroundings. When there is only one seam left between the initial closing of the second pressing plate and the first pressing plate, clean up some stains that may exist on the auxiliary material, and push it out from the center to the surroundings to prevent Crush the pressure plate or circuit board during the crimping process. Quickly return to the position after the cleaning is completed, and the total time of pushing out and retracting is controlled at 10 seconds. The packing column 500 and the second pressing plate are made of the same material. It plays a pressing role in the normal pressing process and is processed by a precision machine tool with the second pressing plate, and the bonding is seamless. After the bladder assembly 522 has cleaned the surface, the heater inside the hot pressing plate 511 will increase the temperature of the whole, improve the adhesion between the auxiliary material and the circuit board, and will not cause damage to the bladder assembly 522 itself.

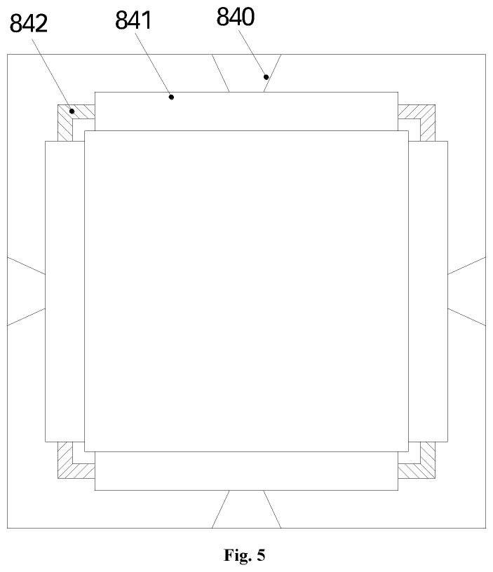

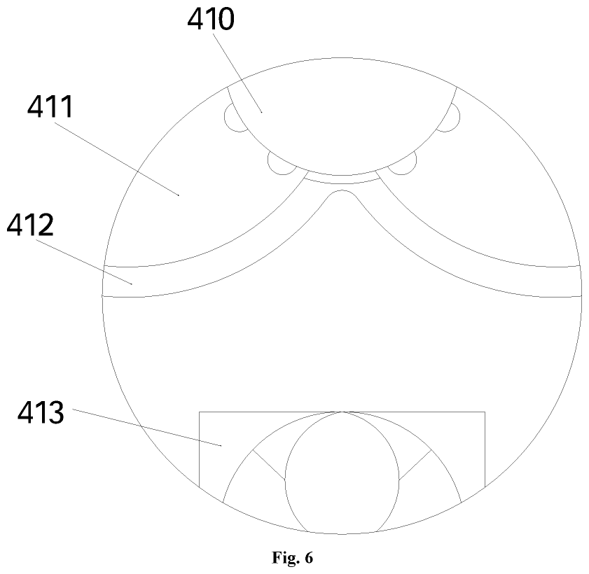

As shown in FIG. 5 to FIG. 6, the end of the multi-functional processing structure 841 close to the outer side of the first pressure plate is connected with a hydraulic column 840. The multi-functional processing structure 841 is hidden 3 cm inside the first pressing plate when it is not in operation. The hydraulic column 840 can be pushed out as soon as it runs. Both ends of the four multi-functional processing structures 841 are vertically connected with meshing tooth columns 842, and the meshing tooth columns 842 mesh with each other so that the four multi-functional processing structures 841 form a four-way linkage mechanism. The end of the multi-functional processing structure 841 in contact with the circuit board is an overflow groove 410. Taking the dividing line between the overflow groove 410 and the heat sealing clip 413 as the base axis, each rotation angle is 180°, and the multi-functional processing structure 841 is wrapped in a layer of square iron sheet so that it is parallel to the first pressing plate The surface is the same horizontal line, and the circuit board can be touched by just ascending 3 cm during use. The four multi-functional processing structures 841 are closely attached to the four sides of the circuit board, so that all the spilled gel can be absorbed and refluxed without moving and interfering with other positions on the circuit board. The angle of rotation between the overflow groove 410 and the heat-sealing clamp 413 is constant, which can ensure that the opening is aligned with the edge position of the circuit board every time it rotates, preventing useless work.

As shown in FIG. 6, the overflow groove 410 is a semicircular structure with an upward opening. Two backflow belts 412 are also connected to the bottom of the overflow groove. Both the lower left corner and the lower right corner of the overflow groove 410 are connected with two inverted suction openings. The angle between the semicircular structure with the opening upward and the horizontal line of the circuit board is 45°. The overflowing glue will not only be sucked in by the suction port and automatically settle to the bottom and flow out from the backflow belt 412, but also flow into the bottom of the semi-circular structure and flow out along the backflow belt 412 in a natural overflow state. The two backflow belts 412 can separate the incoming colloid to improve containment and fluidity.

As shown in FIG. 6, the two reverse flow belts 412 form a figure-eight structure with a top seal. The figure-eight refers to the shape of Chinese character “A” that means eight in Chinese. The connecting end at the bottom of the backflow bag 412 is chamfered, and a check valve is installed at the connection between the top and the overflow groove 410. The chamfering of the connecting end can quickly diverge the influx of glue to both ends without accumulating on it. The middle bit. The one-way valve can prevent the inflowing glue from leaking out when it is rotated and adjusted to the heat-sealing clamp 413 state.

As shown in FIG. 6, the heat-sealing clip 413 has an inverted bowl-shaped structure. The left and right ends of the inside of the heat sealing clip are connected with snap clips. An oval clip with a downward opening is connected to the middle of the snap clip. The snap clip will pop out so that the oval clip clamps the edge of the circuit board, and then performs reciprocating motion. The auxiliary material and the circuit board are better sealed, so that the staff will not affect the pressing effect due to excessive glue overflow during the transfer and can maintain the auxiliary material and the circuit board in a relatively stable state before the heat drying.

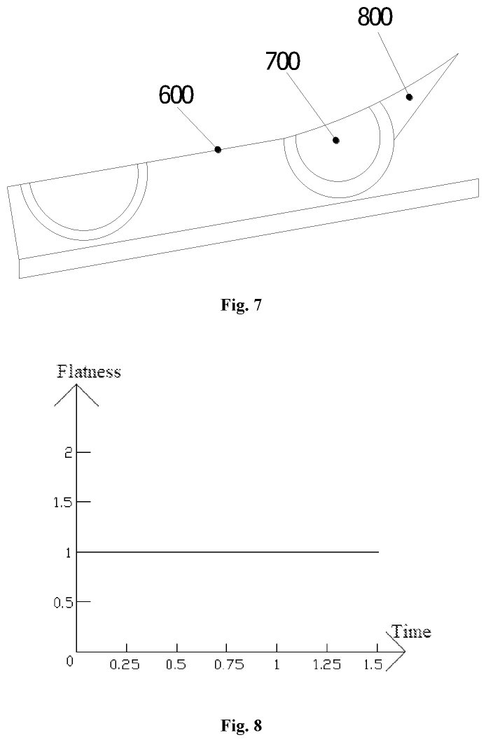

As shown in FIG. 7, the front and rear ends of the top of the lower working position of the lower film part 80 are equipped with guide rails 600. The inner part of the guide rail 600 is connected with two chucking wheels 700, and the first contact with the circuit board is the chucking wheel 700 is in a static state, and the second chucking wheel 700 is in an intermittent motion state. A guide piece 800 is connected to the top corner of one end of the guide rail 600 facing the initial movement direction of the circuit board. The guide piece 800 is adjusted to an angle of 60°-120° based on the vertical line. The guide piece 800 can guide the direction of the circuit board sliding from above, and the opening and closing degree is adjusted according to the sliding height of the circuit board. If the circuit boards are stacked high, for safety reasons, the opening of the guide piece 800 is rotated to 120° to ensure that the circuit board will not fall to a position outside the processing area when it is dropped. The first described chucking wheel 700 is to limit the movement of the circuit board within a fixed range and play a guiding and guiding role. The second described chucking wheel 700 will have an intermittent ejection and expansion action to decelerate the circuit board so that it can reach the designated coating area and prevent it from directly bounce to the conveyor belt 83 without attaching the high-temperature film when it slides.

The above are only the preferred embodiments of the present disclosure and are not used to limit the present disclosure. For those skilled in the art, the present disclosure can have various modifications and changes. Any modification, equivalent replacement, improvement, etc. made within the spirit and principle of the present disclosure shall be included in the protection scope of the present disclosure.

What is claimed is:

1. An automatic roll-to-roll quick press for flexible plates, comprising:
a lower film part (80) and
an upper film part (81) parallel and movably attached to the lower film part (80);
a right end of the lower film part (80) is vertically connected to a transmission belt (83); a right end of the transmission belt (83) is connected with a first pressing part (84); a top of the first pressing part (84) is connected with a second pressing part (82); a second pressing plate part of the second pressing part (82) comprises a flatness detection tube (823); there are four large infrared detectors inside the flatness detection tube (823), and four small infrared detectors inside; the detector scans a total of eight directions, and the scanning area covers the entire cylinder; inside a center of the second pressing part (82) is hidden a punching bag assembly (522); the second pressing plate is a seamless smooth surface when the punching bag assembly (522) is not running; a first pressing plate part of the first pressing part (84) comprises four multi-functional processing structures (841); the four multi-functional processing structures (841) enclose the circuit board tightly; the multi-functional processing structure (841) comprises an internal rotating drum (411), which is divided into upper and lower parts; an overflow groove (410) on the upper part of the internal rotating drum (411) first contacts the circuit board; and a component that capable of being rotated upwards from the bottom is a heat-sealing clamp (413).

2. The quick press according to claim 1, wherein the flatness detection cylinder (823) further comprises an L-shaped buckle (822) connected to its left and right ends, one end of a short shaft of the L-shaped buckle (822) is inserted into a shaft center of the flatness detection tube (823), and one end of the long shaft is fixed with a steering shaft (821); the steering shaft (821) is vertically inserted and embedded in the sliding wheel (820); the sliding wheel (820) drives the entire flatness detection cylinder (823) to perform a uniform linear motion in the grooves on the front and back sides of the second pressure plate.

3. The quick press according to claim 1, wherein the punching bag assembly (522) is movably connected to the bottom inside the second pressure plate, and there are four punching bag assemblies; the four punching bag assemblies are distributed on right up, right down, left, and right positions on basis of a top view of the second pressing plate; the top of one end of the punching bag assembly (522) near the outer end is provided with a filling column (500), which interacts with the second pressing plate when the filling column is not moving; the bottom of the filling column (500) and the bottom of the punching bag assembly (522) are both connected with the hot pressing plate (511) which has a solid structure and better heat conduction effect.

4. The quick press according to claim 1, wherein the end of the multi-functional processing structure (841) close to the outer side of the first press plate is connected with a hydraulic column (840); the multi-functional processing structure (841) is hidden 3 cm inside the first pressure plate when it is not in operation, and the hydraulic column (840) can be pushed out as soon as it runs; two of the four multi-functional processing structures (841); both ends are vertically connected with a meshing tooth column (842), and the meshing tooth columns (842) mesh with each other so that the four multi-functional processing structures (841) form a four-way linkage mechanism; the multi-functional processing structure (841); the end in contact with the circuit board is an overflow groove (410), and the dividing line between the overflow groove (410) and the heat-sealing clamp (413) is the base axis, and each rotation angle is 180°.

5. The quick press according to claim 4, wherein the overflow groove (410) is a semicircular structure with an upward opening, and its bottom is also connected with two reverse flow belts (412), and two reverse suction openings are connected to the lower left corner and the lower right corner of the overflow groove (410).

6. The quick press according to claim 5, wherein the two reverse flow belts (412) form a top-sealed figure eight-shaped structure, and the bottom connecting end is chamfered, and a check valve is installed at the top of the joint with the overflow groove (410).

7. The quick press according to claim 4, wherein the heat-sealing clamp (413) is an inverted bowl-shaped structure, and the left and right ends of the inside are connected with the snap clip; an oval clip with a downward opening is connected in the middle of the snap clip.

8. The quick press according to claim 4, wherein the front and rear ends of the top of the lower station of the lower laminating part (80) are installed with guide rails (600), the inner part of the guide rail (600) is connected with two chucking wheels (700), the first chucking wheel (700) in contact with the circuit board is in a static state, and the second chucking wheel (700) is in intermittent motion In the state, the top corner of the guide rail (600) facing the initial movement direction of the circuit board is connected with a guide piece (800), and the guide piece (800) is adjusted to an angle of 60°-120° based on the vertical line.
